(19) United States
(12) Patent Application Publication
(10) Pub. No.: US 2023/0287183 A1
(43) Pub. Date: Sep. 14, 2023

(54) CURABLE SILICONE COMPOSITION

(71) Applicant: DuPont Toray Specialty Materials Kabushiki Kaisha, Tokyo (JP)

(72) Inventors: Shunya TAKEUCHI, Chiba (JP); Akihiko KOBAYASHI, Chiba (JP)

(21) Appl. No.: 18/178,253

(22) Filed: Mar. 3, 2023

(30) Foreign Application Priority Data
Mar. 10, 2022 (JP) 2022-037543

(51) Int. Cl. C08G 77/20; C08G 77/00; C08G 77/12; C08G 77/08; H01L 33/56; H01L 23/29

(52) U.S. Cl. CPC C08G 77/20; C08G 77/80; C08G 77/12; C08G 77/08; H01L 33/56; H01L 23/296

(57) ABSTRACT

A curable silicone composition of the present invention contains certain quantities of straight-chain organopolysiloxane which has at least two alkenyl groups and bound to silicon atoms and ≥0 mol % and <5 mol % of aryl groups per molecule, organopolysiloxane resin having at least two alkenyl groups bound to a silicon atom in the molecule, organohydrogenpolysiloxane resin which has a network molecular structure with at least two hydrogen atoms bound to a silicon atom per molecule, organohydrogenpolysiloxane resin which has a network molecular structure with at least two hydrogen atoms bound to a silicon atom per molecule, only at the end of the molecule, and hydrosilylation reaction catalyst, and (total mols of silicon-atoms-bound) hydrogen atoms/(total mols of silicon-atom-bound alkenyl groups) in the organopolysiloxane in the composition=1-3.

### CROSS-REFERENCE TO RELATED APPLICATIONS

This application claims priority pursuant to 35 U.S.C. 119(a) to Japanese Application No. 2022-037543, filed Mar. 10, 2022, which application is incorporated herein by reference in its entirety.

### TECHNICAL FIELD

This disclosure relates to curable silicone compositions, hardened material thereof, semiconductor sealing material compositions comprising such a composition, semiconductor devices wherein a semiconductor element is sealed with such a composition, and a process for producing semiconductor devices.

### BACKGROUND ART

Hardened material from a curable silicone composition cured by a hydrosilylation reaction is water-repellence, transparency, heat resistance, low-temperature resistance, electrical insulating properties and weather resistance. For this reason, various curable silicone compositions are widely used industrially. JP 2010 174233 A (Patent Document 1) describes curable silicone compositions which include alkenyl-group-containing alkylpolysiloxane, resinous alkenyl-group-containing organopolysiloxane, organopolysiloxane which has hydrogen atoms bound to a silicon atom, and has SiO4/2 units, straight-chain organopolysiloxane has hydrogen atoms bound to a silicon atom and a hydrosilylation reaction catalyst. JP 2018-131583 A (Patent Document 2) mentions employing a curable silicone composition which includes straight-chain organopolysiloxane having at least two alkenyl groups, branched organopolysiloxane having at least two alkenyl groups, branched organohydrogenpolysiloxane containing at least hydrogen atoms bound to a silicon atom, straight-chain organohydrogenpolysiloxane containing a least two hydrogen atoms bound to a silicon atom, and a solvent, as die-attach material for photosemiconductor devices.

In particular, hardened material which is less prone than other organic materials to coloration and shows little decrease in physical properties is suitable for covering and/or sealing optical elements. For example, WO 2018/062009 (Patent Document 3) describes sealing photosemiconductor elements with hardened material of a curable silicone composition comprising at least straight-chain organopolysiloxane which has at least two silicon-atom-bound alkenyl groups per molecule, and in which at least 5 mol % of the total organic groups bound to a silicon atom are aryl groups; organopolysiloxane comprising siloxane units indicated by the formula: R13SiO1/2 (in the formula, the R1s are the same or different monovalent hydrocarbon groups) and siloxane groups indicated by the formula SiO4/2, in which alkenyl group content is at least 6 wt %, organopolysiloxane which has at least two hydrogen atoms per molecule bound to silicon atoms, and a hydrosilylation catalyst And JP 2016-204423 A (Patent Document 6) describes covering light-emitting elements with hardened material of an addition-cured silicone composition which includes organopolysiloxane with a network structure, which has at least two alkenyl groups per molecule, straight-chain organopolysiloxane which has at least two alkenyl groups per molecule, branched organohydrogen-polysiloxane which has at least two alkenyl groups per molecule, straight-chain organohydrogenpolysiloxane which has at least two alkenyl groups per molecule, and a hydrosilylation catalyst.

JP 2010-229402 A (Patent Document 5) describes photosemiconductor sealing compositions which include alkenyl-group-containing straight-chain organopolysiloxane, alkenyl-group-containing organopolysiloxane resin, straight-chain organohydrogenpolysiloxane, and a branched organohydrogenpolysiloxane compound liquid at 25° C. However, Patent Document 5 does not mention organohydrogenpolysiloxane having a network molecular structure. JP 2012-12433 A (Patent Document 6), Example 2, describes curable organopolysiloxane compositions which include vinyl-group-containing straight-chain organopolysiloxane, vinyl-group-containing organopolysiloxane resin, straight-chain organohydrogenpolysiloxane in which the D-unit has a hydrogen atom bound to a silicon atom, and organohydrogenpolysiloxane resin. JP 2015-78375 A (Patent Document 7) describes curable compositions which include straight-chain organopolysiloxane which has at least two silicon-atom-bound alkenyl groups per molecule with at least 30 mol % of the monovalent hydrocarbon groups bound to a silicon atom being aryl groups, and branched chain organopolysiloxane, and which include straight-chain organopolysiloxane which at least two silicon-atom-bound hydrogen atoms per molecule with at least 15 mol % of the total silicon-atom-bound organic groups being aryl groups and branched-chain organopolysiloxane.

However, heat-curing at a high temperature for a long time may be necessary in order to form hardened material from curable silicone compositions cured by a hydrosilylation reaction. For example, the examples of Patent Documents 2-7 discussed above mention that the curable silicone compositions were cured by heating at 150° C. for at least 1 hour, etc. This long curing time leads to lowered productivity. Moreover, when heating for a long time at a high temperature is necessary in order to cure a curable silicone composition, the electronic device on which the curable silicone composition is used may be damaged by heating. Because of this, there is a demand for curable silicone compositions which can be cured in a short time at a low temperature. Increasing the quantity of hydrosilylation catalyst could be considered as one way of curing curable silicone compositions in a short time at a low temperature. However, when there is a large quantity of hydrosilylation catalyst in a curable silicone composition, there is marked coloration of the hardened material and it may not be useable for applications requiring transparent hardened material, such as sealing photo semiconductor elements, etc.

Moreover, curable silicone compositions cured by a hydrosilylation reaction may undergo a considerable shrinkage in volume during curing. This volume shrinkage can cause curling of flexible films and decreased control of flatness and thickness. Moreover, in order to heighten process efficiency in processes such as sealing photosemiconductor elements with a curable silicone composition, it is important that the curable silicone composition has a low viscosity. In addition, low viscosity in a curable silicone composition is important for self-levelling properties required in screen-printing processes, etc.

### PRIOR ART DOCUMENTS

### Patent Documents

[Patent Document 1] JP 2010-174233 A
[Patent Document 2] JP 2018-131583 A
[Patent Document 3] WO 018/062009 A1
[Patent Document 4] JP 2016-204423 A
[Patent Document 5] JP 2010-229402 A
[Patent Document 6] JP 2012-12433 A
[Patent Document 7] JP 2015-78375 A

### SYNOPSIS OF THE INVENTION

### Problem which the Invention is Intended to Solve

The object of the present invention is to offer curable silicone compositions which can be cured at low temperature in a short time, and which show little volume shrinkage during curing, have a low catalyst content and have a low viscosity. A further object of the present invention is to offer semiconductor sealing material compositions comprising such a composition, semiconductor devices wherein a semiconductor element is sealed with hardened material of such a composition, and a process for producing semiconductor devices which includes sealing photosemiconductor elements with hardened material of such a composition.

### Means for Solving the Problem

As the result of concerted studies directed towards the problem above, it was discovered that the object of the present invention can be achieved with a curable silicone composition cured by a hydrosilylation reaction, the object of the present invention is achieved by having a specified ratio of (A) straight-chain organopolysiloxane which has at least two alkenyl groups bound to a silicon atom, (B) organopolysiloxane resin which has at least two alkenyl groups bound to a silicon atom, (C) organohydrogenpolysiloxane resin containing at least two hydrogen atoms bound to a silicon atom, and (D) straight-chain organohydrogenpolysiloxane containing at least two hydrogen atoms bound to a silicon atom; and having a ratio of the total mols of hydrogen atoms bound to a silicon atom in the total organopolysiloxane included in the composition relative to the total mols of alkenyl groups bound to a silicon atom in the total organopolysiloxane included in the composition within a desired range.

In order to solve the aforementioned problem, one aspect of the present invention offers a curable silicone composition below:
A curable silicone composition, which is a curable silicone composition which includes:
   (A) straight-chain organopolysiloxane which has at least two alkenyl groups bound to silicon atoms per molecule, and a total quantity of aryl groups bound to silicon atoms of ≥0 mol % and <5 mol % based on the total mols of organic groups bound to silicon atoms: 20-74 mass % based on the total mass of organopolysiloxane having alkenyl groups bound to a silicon atoms and organopolysiloxane having hydrogen atoms bound to a silicon atom in the composition,
   (B) organopolysiloxane resin having at least two alkenyl groups bound to silicon atoms per molecule: 20 mass % to 50 mass % based on the total mass of organopolysiloxane having alkenyl groups bound to a silicon atoms and organopolysiloxane having hydrogen atoms bound to a silicon atom in the composition,
   (C) organohydrogenpolysiloxane resin which has a network molecular structure with at least two hydrogen atoms bound to a silicon atom per molecule: 1-15 mass % based on the total mass of organopolysiloxane having at alkenyl groups bound to a silicon atom and organopolysiloxane having hydrogen atoms bound to a silicon atom in the composition,
   (D) straight-chain organohydrogenpolysiloxane having at least two hydrogen atoms bound to a silicon atom per molecule, with hydrogen atoms bound to a silicon atom only present at the two ends of the molecule: 5-27 mass % based on the total mass of organopolysiloxane having alkenyl groups bound to a silicon atom and organopolysiloxane having hydrogen atoms bound to a silicon atoms in the composition, where the mass percentage above for constituent (D) in the composition is higher than the mass percentage for constituent (C), and
   (E) a hydrosilylation reaction catalyst: a quantity, which is a catalytic quantity, of <15 ppm as the quantity of metal atoms included in the catalyst based on the total mass of organopolysiloxane having alkenyl groups bound to a silicon atom and organopolysiloxane having hydrogen atoms bound to a silicon atom in the composition;
(total mols of hydrogen atoms bound to silicon atoms in the total organohydrogenpolysiloxane included in the composition)/(total mols of alkenyl groups bound to silicon atoms in the total)=1-3.
One aspect of the present invention offers hardened material of a curable silicone composition described above.
One aspect of the present invention offers photosemiconductor sealing material compositions comprising a curable silicone composition described above.
One aspect of the present invention offers photosemiconductor devices in which the photosemiconductor elements are sealed with hardened material of curable silicone composition described above.
Moreover, one aspect of the present invention offers a process for producing photosemiconductor devices, which includes sealing photosemiconductor elements with hardened material of a curable silicone composition described above.

### Effects of the Invention

The curable silicone compositions in one embodiment of the present invention present the effects that curing is possible in a short time and at low temperature, viscosity is low, there is little volume shrinkage during hardening of the curable silicone composition, and there is little change in the color of the hardened material.

### SIMPLIFIED DESCRIPTION OF THE DRAWINGS

FIG. 1. is a cross-sectional drawing of an LED which is an example of a photosemiconductor device of the present invention

### MODE FOR CARRYING OUT THE INVENTION

Constituent (A) in a curable silicone composition of the present invention is straight-chain organopolysiloxane which has at least two alkenyl groups bound to a silicon atom per molecule, and a total quantity of aryl groups bound to a silicon atom of ≥0 mol % and <5 mol % based on the total mols of organic groups bound to a silicon atom. Constituent (A) can be one of the principal agents (base polymers) in the composition. In an embodiment of the present invention, the quantity of constituent (A) included in the curable silicone composition, based on the total mass of organopolysiloxane having alkenyl groups bound to a silicon atom and organopolysiloxane having hydrogen atoms bound to a silicon atom in the composition, can be 20-74 mass %, 21-73 mass %, 25-65 mass %, 35-60 mass %, 40-60 mass %, or 45-50 mass %.

In the descriptions “based on the total mass of organopolysiloxane having alkenyl groups bound to a silicon atom and organopolysiloxane having hydrogen atoms bound to a silicon atom in the composition”, and “(total mols of hydrogen atoms bound to a silicon atom in the total organopolysiloxane included in the composition)/(total mols of alkenyl groups bound to a silicon atom in the total organopolysiloxane included in the composition)” in this specification, the term “organopolysiloxane” includes straight-chain organopolysiloxanes and organopolysiloxane resins; and there is no particular restriction as to the structure of the organopolysiloxanes specified by this term “organopolysiloxane”. In this specification, constituent (A) and constituent (B) fall into the category of “organopolysiloxane having alkenyl groups bound to a silicon atom”. Moreover, “organopolysiloxane having alkenyl groups bound to a silicon atom” can also include organopolysiloxanes other than constituent (A) and constituent (B), such as, for example, straight-chain organopolysiloxane having one alkenyl group bound to a silicon atom, straight-chain organopolysiloxane which has at least two alkenyl groups bound to a silicon atom per molecule, and a quantity of aryl groups bound to a silicon atom of ≥5 mol % based on the total mols of organic groups bound to a silicon atom, organopolysiloxane resin having one alkenyl group bound to a silicon atom, and organopolysiloxane having alkenyl groups bound to a silicon atom, employed as an agent conferring adhesion (G).

In this specification, constituent (C) and constituent (D) fall into the category of “organopolysiloxane having hydrogen atoms bound to a silicon atom”. On the other hand, “organopolysiloxane having hydrogen atoms bound to a silicon atom” can also include organopolysiloxanes other than constituent (C) and constituent (D), such as, for example, organohydrogenpolysiloxane resins which have at least two hydrogen atoms bound to a silicon atom per molecule and have branched chain (not network) molecular structure, organohydrogenpolysiloxane resins containing one hydrogen atom bound to a silicon atom, and straight-chain organohydrogenpolysiloxane containing one hydrogen atom bound to a silicon atom.

Examples of alkenyl group which can be included in constituent (A) include C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group; a vinyl group is preferred. In addition, examples of organic groups other than alkenyl groups bound to silicon atoms in constituent (A) include monovalent hydrocarbon groups which do not have an aliphatic unsaturated carbon bond, and specifically C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C6-12 aryl groups such as a phenyl group, tolyl group, xylyl group and naphthyl group; C7-12 aralkyl groups such as a benzyl group, phenethyl group and phenylpropyl group; and halogen-substituted C1-12 alkyl groups such as a 3-chloropropyl group and a 3,3,3-fluoropropyl group. However, in constituent (A) the quantity of aryl groups bound to a silicon atom based on the total mols of organic groups bound to a silicon atom is ≥0 mol % and <5 mol %, preferably ≥0 mol % and ≤2 mol %, and more preferably 0 mol %.

The straight-chain alkenyl-group-containing organopolysiloxane of constituent (A) can have alkenyl groups bound to a silicon atom only at the ends of the molecule, can have them only in a diorganosiloxane repeating unit of the molecule, or can have them both at the end of the molecule and in a diorganosiloxane repeating unit of the molecule. In one embodiment of the present invention, the straight-chain alkenyl-group-containing organopolysiloxane of constituent (A) has alkenyl groups bound to a silicon atom only at both ends of the molecule.

The straight-chain alkenyl-group-containing organopolysiloxane of constituent (A) can be represented by the general formula:

R13SiO(R12SiO)nSiR13.
In the formula the R1s are the same or different monovalent hydrocarbon groups, and specific examples of R1 include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C2 12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group, C6-12 aryl groups such as a phenyl group, tolyl group, xylyl group and naphthyl group; C7-12 aralkyl groups such as a benzyl group, phenethyl group and phenylpropyl group; and halogen-substituted C1-12 alkyl groups such as a 3-chloropropyl group and a 3,3,3-fluoropropyl group. However, at least two R1s are alkenyl groups, and ≥0 mol % and <5 mol % of all R1s are aryl groups. In addition, in the formula n is an integer ≥1, and is preferably an integer 10-1000, and more preferably an integer 30-800.

Examples of constituent (A) include dimethylpolysiloxane with both ends of the molecular chain terminated with dimethylvinylsiloxy groups, a dimethylsiloxane/methylphenylsiloxane copolymer with both ends of the molecular chain terminated with dimethylvinylsiloxy groups, a dimethylsiloxane/methylvinylsiloxane copolymer with both ends of the molecular chain terminated with dimethylvinylsiloxy groups, a dimethylsiloxane/methylvinylsiloxane copolymer with both ends of the molecular chain terminated with trimethylsiloxy groups, and a dimethylsiloxane/methylvinylsiloxane/methylphenylsiloxane copolymer with both ends of the molecular chain terminated with trimethylsiloxy groups, and mixtures of two or more thereof. In one embodiment of the present invention, constituent (A) can be dimethylpolysiloxane with both ends of the molecular chain terminated with dimethylvinylsiloxy groups. A single constituent (A) can be employed, or two or more can be used together.

In one embodiment of the present invention, constituent (A) has a number-average molecular weight of ≤200,000, and preferably has a number average molecular weight of ≤150,000 and more preferably ≤100,000. Organopolysiloxane of constituent (A) preferably has a number-average molecular weight of at least 1000, and more preferably has a number average molecular weight of at least 1500. The values for number-average molecular weight (Mn) and weight-average molecular weight (Mw) in this specification are values measured by gel permeation chromatography using polystyrene standards. In one embodiment of the present invention, the viscosity of constituent (A) at 25° C. is preferably in the range 1-200,000 mPa·s, and more preferably in the range 5-100,000 mPa·s. The viscosity of substances in this specification are viscosities measured at 25° C. with a rotating viscometer in accordance with JIS K7117-1.

Constituent (B) in a curable silicone composition of the present invention is organopolysiloxane resin which has at least two alkenyl groups bound to a silicon atom per molecule. Constituent (B) can be one of the principal agents (base polymers) in the composition. The organopolysiloxane resin as constituent (B) in the present invention includes at least one siloxane unit selected from a set comprising siloxane units represented by R2SiO3/2 (R2 is a monovalent hydrocarbon group) (T units) and siloxane units represented by SiO4/2 (Q units), and is organopolysiloxane resin which has at least two alkenyl groups bound to a silicon atom per molecule. The molecular structure of the organopolysiloxane resin of constituent (B) can be a branching structure or a network structure; it is preferably a network structure. In one embodiment, in constituent (B) the quantity of aryl groups bound to a silicon atom, based on the total mols of organic groups bound to a silicon atom, is ≥0 mol % and <5 mol %, preferably ≥0 mol % and ≤2 mol %, and more preferably 0 mol %.

In one embodiment of the present invention, the quantity of constituent (B) included in the curable silicone composition, based on the total mass of organopolysiloxane having alkenyl groups bound to a silicon atom and organopolysiloxane having hydrogen atoms bound to a silicon atom in the composition, can be 20-50 mass %, 30-50 mass %, 30-45 mass %, or 30-40 mass %.

Specific examples of R2 as a monovalent hydrocarbon group include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group, C6-12 aryl groups such as a phenyl group, tolyl group, xylyl group and naphthyl group; C7 12 aralkyl groups such as a benzyl group, phenethyl group and phenylpropyl group; and halogen-substituted C1-12 alkyl groups such as a 3-chloropropyl group and a 3,3,3-fluoropropyl group.

Examples of alkenyl group which can be included in constituent (A) include C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group; a vinyl group is preferred.

In one embodiment, constituent (B) is represented by the average compositional formula below:
(R23SiO1/2)p (R22SiO2/2)q (R2SiO3/2)r (SiO4/2)s (RO1/2)t, and is organopolysiloxane resin having at least two alkenyl groups bound to a silicon atom in the molecule,
In the formula, each of the R2s, which can be the same or different, is a monovalent hydrocarbon group with at least two R2s per molecule being alkenyl groups; R is a hydrogen atom or a C1-10 alkyl group; p, q, r, s and t represent the respective molar ratios, and the numbers satisfy the following relationships: 0≤p, 0≤q, 0≤r, 0≤s, 0≤t≤0.1, where r+s is ≥0, and p+q+r+s+t=1.
Preferably, 0≤p≤0.8, 0≤q≤0.5, 0≤r≤0.8, 0≤s≤0.8, 0.1r+s0.8, and p+q+r+s+t=1. More preferably, 0.2≤r+s≤0.7, even more preferably, r+s is ≥0.3, and especially preferably r+s is ≥0.35.

Specific examples of R2 in the formula above as a monovalent hydrocarbon group include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group, C6-12 aryl groups such as a phenyl group, tolyl group, xylyl group and naphthyl group; C7-12 aralkyl groups such as a benzyl group, phenethyl group and phenylpropyl group; and halogen-substituted C1-12 alkyl groups such as a 3-chloropropyl group and a 3,3,3-fluoropropyl group. Monovalent hydrocarbon groups as R2 other than alkenyl groups are preferably a methyl group or phenyl group, and more preferably a methyl group.

Examples of alkenyl group which can be included in constituent (D) include C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group; a vinyl group is preferred.

In one embodiment of the present invention, constituent (B) is represented by the formula:

(R23SiO1/2)p1(SiO4/2)s1,
In the formula the R2s are monovalent hydrocarbon groups above, and at least two R2s are alkenyl groups; p1+s1=1, preferably 0.02≤p1≤0.8 and 0.2≤s1≤0.98, and more preferably, 0.5≤p1≤0.7 and 0.3≤s≤0.5.

In one embodiment of the present invention, constituent (B) is represented by the formula:

(R23SiO1/2)p2(R22SiO2/2)g2(R2SiO3/2)r2,
in the formula the R2s are monovalent hydrocarbon groups above, at least two R2s are alkenyl groups, and p2, q2 and r2 are, respectively, 0≤p2≤0.8, 0≤q2≤0.5, 0.1≤r2≤0.9, and the numbers satisfy p2+q2+r2=1.

In one embodiment of the present invention, the organopolysiloxane resin of constituent (B) can be in the liquid state at 25° C., or can be in the solid state. In one embodiment of the present invention, the organopolysiloxane resin of constituent (B) is in the solid state at 25° C.

Constituent (C) in a curable silicone composition of the present invention is organohydrogenpolysiloxane resin which has a network molecular structure with at least two hydrogen atoms bound to a silicon atom per molecule. Constituent (C) can function in the composition as a crosslinking agent. The organohydrogenpolysiloxane resin as constituent (C) in the present invention includes at least one siloxane unit selected from a set comprising siloxane units represented by R2SiO3/2 (R2 is a monovalent hydrocarbon group) (T units) and siloxane units represented by SiO4/2 (Q units), and is organopolysiloxane resin which has a network molecular structure with at least two hydrogen atoms bound to a silicon atom per molecule. In one embodiment, the organohydrogenpolysiloxane resin of constituent (C) does not have an aliphatic unsaturated carbon bond. In one embodiment of the present invention, the quantity of constituent (C) included in the curable silicone composition, based on the total mass of organopolysiloxane having alkenyl groups bound to a silicon atom and organopolysiloxane having hydrogen atoms bound to a silicon atom in the composition, can be 1-15 mass %, 1-10 mass %, 2-7 mass %, 3-7 mass %. or 3-5 mass %.

In one embodiment, constituent (C) is represented by the average compositional formula below:

(R33SiO1/2)u(R32SiO2/2)v(R3SiO3/2)w(SiO4/2)x(R4O1/2)y,
and is an organohydrogenpolysiloxane resin which has a network molecular structure with at least two hydrogen atoms bound to a silicon atom per molecule.
In the formula, each of the R3s, which can be the same or different, is a monovalent hydrocarbon group which does not have an aliphatic unsaturated carbon bond, or a hydrogen atom, with at least two R3s per molecule being hydrogen atoms; R4 is a hydrogen atom or a C1-10 alkyl group; u, v, w, x and y represent the respective molar ratios, and the numbers satisfy the following relationships: 0≤u, 0≤v, 0≤w, 0<x, 0≤y≤0.10, where w+x>0, and u+v+w+x+y=1.
   Preferably, 0.1≤u≤0.8, 0≤v≤0.5, 0≤w≤0.8, 0≤x≤0.8, 0≤y≤0.1, 0.1≤w+x≤0.8, and u+v+w+x+y=1. More preferably, 0.2≤w+x≤0.6, even more preferably, w+x is ≥0.3 and especially preferably ≥0.35.

Specific examples of R3 as a monovalent hydrocarbon group include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C6-12 aryl groups such as a phenyl group, tolyl group, xylyl group and naphthyl group; C7-12 aralkyl groups such as a benzyl group, phenethyl group and phenylpropyl group; and halogen-substituted C1-12 alkyl groups such as a 3-chloropropyl group and a 3,3,3-fluoropropyl group. Monovalent hydrocarbon groups as R3 are preferably a methyl group or phenyl group, and more preferably a methyl group.

R4 is preferably a hydrogen atom, a methyl group or an ethyl group, in these cases, OR4 is a hydroxyl group, a methoxy group or an ethoxy group.

In one embodiment, the organohydrogenpolysiloxane resin which has a network molecular structure, constituent (C). is represented by the formula:

(R33SiO1/2)u1(SiO4/2)x1,
in the formula the R3s are a monovalent hydrocarbon group or a hydrogen atom, and at least two R3s are alkenyl groups; are hydrogen atoms, and u1+x1=1, u1+x1=1; preferably, 0.1 and 0.2≤x1≤0.9, and more preferably 0.5≤u1≤0.7 and 0.3≤x1≤0.5.

In one embodiment, the organohydrogenpolysiloxane resin which has a network molecular structure, constituent (C) is represented by the formula:

(R33SiO1/2)u2(R32SiO2/2)v2(R3SiO3/2)w2,
in the formula the R3s are a monovalent hydrocarbon group or a hydrogen atom, and at least two R3s are hydrogen atoms; and u2, v2 and w2 are, respectively, 0.1≤u2≤0.8, 0≤v2≤0.5 and 0.1≤w2≤0.8, and the numbers satisfy u2+v2+w2=1. In one embodiment, v2=0.

In one embodiment of the present invention, the viscosity of the organohydrogenpolysiloxane resin of constituent (C) at 25° C. is in the range 1-10,000 mPa·s, preferably in the range 2-5,000 mPa·s, and more preferably in the range 3-1000 mPa·s. A single constituent (C) can be employed, or two or more can be used together.

Constituent (D) in a curable silicone composition of the present invention is straight-chain organohydrogenpolysiloxane having at least two hydrogen atoms bound to a silicon atom per molecule, with hydrogen atoms bound to a silicon atom only present at both ends of the molecule. Constituent (D) can function in the composition as a crosslinking agent. In one embodiment of the present invention, the quantity of constituent (D) included in the curable silicone composition, based on the total mass of organopolysiloxane having alkenyl groups bound to a silicon atom and organopolysiloxane having hydrogen atoms bound to a silicon atom in the composition, can be 5-27 mass %, 7-25 mass %, 7-20 mass %, or 13-19 mass %; however, the mass percentage above for constituent (D) in the composition is higher than the mass percentage for constituent (C) (in other words, based on the total mass of organopolysiloxane having at alkenyl groups bound to silicon atoms and organopolysiloxane having hydrogen atoms bound to silicon atoms in the composition, the mass percentage (mass %) of constituent (D) in the composition is higher than the mass percentage (mass %) of constituent (C)). In one embodiment, the straight-chain organohydrogenpolysiloxane of constituent (D) does not have aliphatic unsaturated carbon bonds.

Examples of organic groups bound to a silicon atoms in constituent (D) include monovalent hydrocarbon groups which do not have an aliphatic unsaturated carbon bond, and specifically C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C6-12 aryl groups such as a phenyl group, tolyl group, xylyl group and naphthyl group; C7-12 aralkyl groups such as a benzyl group, phenethyl group and phenylpropyl group; and halogen-substituted C1-12 alkyl groups such as a 3-chloropropyl group and a 3,3,3-fluoropropyl group.

The straight-chain organohydrogenpolysiloxane of constituent (D) has a hydrogen atom bound to a silicon atom only at both ends of the straight-chain organohydrogenpolysiloxane molecule. Thus, the D units in the straight-chain organohydrogenpolysiloxane of constituent (D) do not have a hydrogen atom bound to a silicon atom, and the two M units have a hydrogen atom bound to the silicon atoms.

The straight-chain organohydrogenpolysiloxane of constituent (D) can be represented, for example, by the general formula:

R5′3SiO(R52SiO)nSiR5″3.
In the formula, the R5s, which can be the same or different, are a monovalent hydrocarbon group which does not have an aliphatic unsaturated carbon bond. R5′ is a monovalent hydrocarbon group which does not have an aliphatic unsaturated bond, or a hydrogen atom, where at least one R5′ per molecule is a hydrogen atom. R5″ is a monovalent hydrocarbon group which does not have an aliphatic unsaturated bond, or a hydrogen atom, where at least one R5″ per molecule is a hydrogen atom. Specific examples of monovalent hydrocarbon groups which do not have an aliphatic unsaturated carbon bond include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C6 12 aryl groups such as a phenyl group, tolyl group, xylyl group and naphthyl group; C7-12 aralkyl groups such as a benzyl group, phenethyl group and phenylpropyl group; and halogen-substituted C1-12 alkyl groups such as a 3-chloropropyl group and a 3,3,3-fluoropropyl group. In addition, in the formula n is an integer ≥1, and is preferably an integer 10-1000, and more preferably an integer 30-800.

Examples of constituent (D) include dimethylpolysiloxane with both ends of the molecular chain terminated with dimethylhydrogensiloxy groups, a dimethylsiloxane/methylphenylsiloxane copolymer with both ends of the molecular chain terminated with dimethylhydrogensiloxy groups, and mixtures of two or more thereof. In one embodiment, constituent (D) can be dimethylpolysiloxane with both ends of the molecular chain terminated with dimethylhydrogensiloxy groups. A single constituent (D) can be employed, or two or more can be used together. In one embodiment of the present invention, the curable silicone composition can be a curable silicone composition which does not include straight-chain organohydrogenpolysiloxane with a hydrogen atom bound to a silicon atom present in a D unit.

In one embodiment of the present invention, the straight-chain organohydrogenpolysiloxane of constituent (D) has a viscosity at 25° C. in the range of 1-10,000 mPa·s, preferably in the range 2-5000 mPa·s, and more preferably in the range 3-1000 mPa·s.

In the present invention, the ratio of “total mols of hydrogen atoms bound to a silicon atom in the total organopolysiloxane included in the composition” relative to the “total mols of alkenyl groups bound to a silicon atom in the total organopolysiloxane included in the composition” is in the range 1-3, and thus, [(total mols of hydrogen atoms bound to a silicon atom in the total organopolysiloxane included in the composition)/(total mols of alkenyl groups bound to a silicon atom in the total organopolysiloxane included in the composition)=1-3]. This ratio is more preferably 1-2, and even more preferably 1-1.5. When this ratio is smaller than 1, the curing time of the composition at low temperature becomes long.

The hydrosilylation reaction catalyst (E) in the present invention is a constituent used as the catalyst in order to accelerate the addition reactions (i.e. hydrosilylation reactions) between the alkenyl groups bound to a silicon atom in aforementioned constituent (A) and constituent (B), and the hydrogen atoms bound to silicon atoms in aforementioned constituent (C) and constituent (D). Constituent (E) is a platinum-group-metal catalyst, and can include one or more platinum group metals selected from a group comprising platinum, rhodium, ruthenium, palladium, osmium and iridium. In one embodiment, a platinum-based catalyst, rhodium-based catalyst, and palladium-based catalyst can be given as examples of platinum-group-metal catalysts. The platinum group metal catalyst is preferably a platinum-based catalyst. Examples of platinum-based catalysts include finely powdered platinum, chloroplatinic acid, alcoholic solutions of chloroplatinic acid, platinum-alkenylsiloxane complexes, platinum-olefin complexes and platinum-carbonyl complexes. Examples of alkenylsiloxanes in platinum-alkenylsiloxane complexes include 1,3-divinyl-1,1,3,3-tetramethyldisiloxane, 1,3,5,7-tetramethyl-1,3,5,7-tetravinylc yclotetrasiloxane, alkenyl siloxanes in which some of the methyl groups in these alkenylsiloxanes are replaced by an ethyl group and/or phenyl group, etc., and alkenyl siloxanes in which some of the vinyl groups in these alkenylsiloxanes are replaced by an allyl groups and/or hexenyl group, etc.

The quantity of (E) a hydrosilylation reaction catalyst is a quantity, which is a catalytic quantity, of <15 ppm as the quantity of metal atoms included in the catalyst based on the total mass of organopolysiloxane having alkenyl groups bound to a silicon atom and organopolysiloxane having hydrogen atoms bound to a silicon atom in the composition. The quantity of catalyst in this specification is a quantity which enables the catalyst to catalyze the hydrosilylation reaction. In one embodiment of the present invention, the quantity of catalyst metal atoms included in constituent (E) in the composition, as the quantity of metal atoms included in the catalyst, based on the total mass of organopolysiloxane having alkenyl groups bound to a silicon atom and organopolysiloxane having hydrogen atoms bound to a silicon atom in the composition, is preferably in the range 0.1-15 ppm, and more preferably in the range 0.5-10 ppm. Provided that quantity of constituent (E) is within the range above, coloration of the hardened material formed from the curable silicone composition can be suppressed.

Other than constituents (A)-(E) above, a composition of the present invention can also include discretionary ingredients within ranges which do not detract from the object of the present invention.

In one embodiment of the present invention, the curable silicone composition can include (F) a hydrosilylation reaction control agent in order to give suitable control of the speed of hardening of the curable silicone composition. Examples of hydrosilylation control agents as constituent (F) silylated acetylene compounds such as methyltris(3-methyl-1-butyn-3-oxy)silane, methylvinylbis(3-methyl-1-butyn-3-oxy)silane and trimethyl(cyclohexyl-1-ethyn-1-oxy)silane, alkyne alcohols such as 1 ethynylcyclohexanol, 2-methyl-3-butyn-2-ol, 3,5-dimethyl-1-hexyn-2-ol and 2-phenyl-3-butyn-2-ol, enyne compounds such as 3-methyl-3-penten-1-yne and 3,5-dimethyl-1-hexen-1-yne, alkenylcyclosiloxane compounds such as 1,3,5,7-tetramethyl-1,3,5,7-tetravinylcyclotetrasiloxane and 1,3,5,7-tetramethyl-1,3,5,7-tetrahexenylcyclotetrasiloxane, and benzotriazole. Although there is no restriction in the present invention as to the content of constituent (F), it is preferably in the range 0.001-3 parts by weight in a total of 100 parts by mass of organopolysiloxane having alkenyl groups bound to a silicon atom and organopolysiloxane having hydrogen atoms bound to a silicon atom in the composition.

An addition, in one embodiment of the present invention the curable silicone composition can also contain an adhesion conferring agent (G), in order to raise the adhesion of the hardened material to the substrate with which it is in contact during curing. As constituent (G), an organosilicon compound having per molecule at least one monovalent organic group containing an alkoxy group or epoxy group bound to a silicon atom is preferred. Examples of an alkoxy group here include a methoxy group, ethoxy group, propoxy group, butoxy group and methoxyethoxy group; a methoxy group is particularly preferred. Similarly, examples of epoxy-group-containing monovalent organic groups include glycidoxyalkyl groups such as a 3-glycidoxypropyl group and 4-glycidoxybutyl group, epoxycycloalkylalkyl groups such as a 2-(3,4-epoxycyclohexyl)ethyl group and 3-(3,4-epoxycyclohexyl)propyl group, and oxiranylalkyl groups such as a 4-oxiranylbutyl group and 8-oxiranyloctyl group; a glycidoxyalkyl group is especially preferred. Examples of groups other than monovalent organic groups containing an alkoxy group or epoxy group bound to a silicon atom include substituted or unsubstituted monovalent hydrocarbon groups such as alkyl groups, alkenyl groups, aryl groups, aralkyl groups and haloalkyl groups, acrylic-group-containing monovalent hydrocarbon groups such as a 3-methacryloxypropyl group, and a hydrogen atom. This organosilicon compound preferably has (a) silicon-atom-bound alkenyl group or silicon-atom-bound hydrogen atom. In addition, this organosilicon compound preferably has at least one epoxy-group-containing monovalent hydrocarbon group per molecule, because this can confer good adhesion for different types of substrate. Organosilane compounds, organosiloxane oligomers and alkyl silicates are examples of such organosilicon compounds. The molecular structure of the organosiloxane oligomers or alkyl silicates here can take the form of straight-chain, straight-chain with one branch, branched-chain, cyclic or a network, for example; but straight-chain, branched-chain or network form is particularly preferred. Specific examples of such organosilicon compounds include silane compounds such as 3-glycidoxypropyltrimethoxysilane, 2-(3,4-epoxycyclohexyl)ethyltrimethoxysilane, 3-methacryloxypropyltrimethoxysilane, siloxane compounds which have at least one silicon-atom-bound alkenyl group or silicon-atom-bound hydrogen atom and one silicon-atom-bound alkoxy group per molecule, mixtures of a silane compound or siloxane compound which has at least one silicon-atom-bound alkoxy group per molecule, and a siloxane compound which have at least one silicon-atom-bound hydroxyl group and silicon-atom-bound alkenyl group per molecule, methyl polysilicate, ethyl polysilicate, epoxy-group-containing ethyl polysilicate, and organopolysiloxanes which contain an epoxy group and an alkenyl group, represented by the average compositional formula: R6hR7iSiO (4−h−i)/2.

In these organopolysiloxanes which contain an epoxy group and an alkenyl group, R6 in the formula is an epoxy-group-containing monovalent organic group, exemplified by the same groups mentioned above; it is preferably a glycidoxyalkyl group. And R7 is a C1-12 alkyl group, C2-12 alkenyl group, C6-12 aryl group, or C7 12 aralkyl group, exemplified by the same groups mentioned above. Where ≥1 mol % of all R7s is/are (an) alkenyl group(s), and preferably ≥3 mol %, or >10 mol % is (an) alkenyl group(s). At least 3 mol %, or at least 10 mol %, of all R7s is/are preferably (a) phenyl group(s). h is a number within the range 0.05-1.8, and preferably a number within the range 0.05-0.7, or a number within the range 0.1-0.6. Similarly, i is a number in the range 0.10-1.80, and preferably a number in the range 0.20-1.80. Such organopolysiloxanes which contain an epoxy group and an alkenyl group can be prepared by cohydrolysis of an epoxy-group-containing alkoxysilane and alkenyl-group-containing organosilane. It should be noted that the epoxy-group-containing organopolysiloxane can also contain a small quantity of alkoxy groups derived from the starting material thereof.

There is no particular restriction in the present invention as to the content of constituent (G). When constituent (G) is organopolysiloxane having silicon-atom-bound alkenyl groups or silicon-atom-bound hydrogen atoms, the content of constituent (G) based on the total mass of organopolysiloxane having alkenyl groups bound to a silicon atom and organopolysiloxane having hydrogen atoms bound to a silicon atom in the composition is preferably in the range 0.01-10 mol %. When constituent (G) is not organopolysiloxane having silicon-atom-bound alkenyl groups or silicon-atom-bound hydrogen atoms, the content of constituent (G) per a total of 100 parts by mass of organopolysiloxane having alkenyl groups bound to a silicon atom and organopolysiloxane having hydrogen atoms bound to a silicon atom in the composition is preferably in the range 0.01-10 mol %.

These compositions can also include further discretionary ingredients other than the constituents discussed above, provided that they do not detract from the object of the present invention. Examples of other discretionary ingredients which can be included in these compositions include inorganic fillers, organic fillers, phosphors, heat resistance agents, dyes, pigments, fire-proofing agents, additives for adjusting surface tension for leveling during screen printing (polydimethylsiloxane (PDMS) oil, modified oil or silane coupling agents, etc.), antioxidants (cerium, etc.), weather resistance agents, and solvents.

As inorganic fillers, a reinforcing filler as constituent (B) examples of reinforcing fillers for conferring mechanical strength on the hardened material and raising protection or adhesion, etc., include fumed silica, precipitated silica, fused silica, baked silica, fumed titanium dioxide, quartz, calcium carbonate, silicon diatomite, aluminum oxide aluminum hydroxide, zinc oxide, zinc carbonate and glass beads, because they confer mechanical strength on the hardened material and raise protection or adhesion. These reinforcing fillers can also be surface-treated with an organoalkoxysilane such as methyltrimethoxysilane, an organohalosilane such as trimethylchlorosilane, an organosilazane such as hexamethyldisilazane, or an siloxane oligomer selected from α,ω-silanol group-terminated dimethylsiloxane oligomers, α,ω-silanol group-terminated methylphenylsiloxane oligomers, and α,ω-silanol group-terminated methylvinylsiloxane oligomers etc. Further reinforcing fillers include fiber fillers such as calcium metasilicate, potassium titanate, magnesium sulfate, zeolite, Zonolite, aluminum borate, rock wool and glass fiber.

Inorganic fillers can also be heat-conducting fillers or electrically-conducting fillers; heat-conducting fillers or electrically-conducting fillers include finely powdered metals such as gold, silver, nickel, copper or aluminum, fine powders of finely powdered ceramic, glass, quartz or organic resin, etc., with a metal such as gold, silver, nickel or copper vapor deposited or plated onto the surface thereof, metal compounds such as aluminum oxide, magnesium oxide, aluminum nitride, boron nitride and zinc oxide, graphite, and mixtures of two or more thereof.

Pigments include, for example, white pigments and black pigments; white pigments include metal compounds such as titanium dioxide, aluminum oxide, zinc oxide, zirconium oxide and magnesium oxide, hollow fillers such as glass balloons and glass beads, and also barium sulfate, zinc sulfate, barium titanate, aluminum nitride, boron nitride and antimony oxide As a black pigment there is carbon black.

Examples of phosphors include yellow, red, green and blue phosphors comprising oxide-based phosphors, oxynitride-based phosphors, nitride-based phosphors, sulfide-based phosphors, oxysulfide-based phosphors or fluoride-based phosphors, etc., and mixtures of at least two of these, widely employed in light-emitting diodes (LEDs). Examples of oxide-type phosphors include cerium ion-doped yttrium-aluminum-garnet type YAG green-yellow light-emitting phosphors, cerium ion-doped terbium-aluminum-garnet type TAG yellow light-emitting phosphors, and cerium and europium ion-doped silicate green-yellow-light-emitting phosphors. Examples of oxynitride-type phosphors include europium ion-doped silicon-aluminum-oxygen-nitrogen type SiAlON red-green light-emitting phosphors. Examples of nitride-type phosphors include europium ion-doped calcium-strontium-aluminum-silicon-nitrogen type CASN red light-emitting phosphors. Examples of sulfide-type phosphors include copper ion or aluminum ion-doped ZnS green light-emitting phosphors. Examples of oxysulfide-type phosphors include europium ion-doped Y202 red light-emitting phosphors. A single one of these phosphors can be employed, or a combination of various types can be employed.

Organic fillers include fine particulate silicones, for example, fine particulate non-reactive silicone resins and fine particulate silicone elastomers. Fine particulate silicone elastomers can take various forms, such as round, flattened and irregularly shaped, but from the point of view of dispersability they are preferably round, and within this they are more preferably spherical.

Provided that there is no adverse effect on the object of the invention, there is no restriction as to the quantities of discretionary ingredients. For example, in one embodiment of the present invention, the composition can include (a) phosphor(s) in a quantity of 10-80 mass % based on the total mass of this composition. In one embodiment of the present invention, the composition can also include an inorganic filler, for example titanium oxide, in a quantity of 10-80 mass % based on the total mass of this composition. In one embodiment of the present invention, the composition can include a pigment, for example carbon black, in a quantity of 0.01-50 mass % based on the total mass of this composition. In one embodiment of the present invention, the composition can include silica, for example fumed silica, in a quantity of 0.01-80 mass % based on the total mass of this composition.

In one embodiment of the present invention, the quantity of organopolysiloxane having alkenyl groups bound to a silicon atom and organopolysiloxane having hydrogen atoms bound to a silicon atom in the composition, based on the total mass of the composition should be ≥20 mass %, ≥40 mass %, ≥60 mass %, ≥80 mass %, or ≥90 mass %, and should be ≤97 mass % or ≤99 mass %.

Although this composition will promote curing at room temperature or by heating, heating is preferred in order to speed up curing. This heating temperature is preferably in the range 50-200° C., and more preferably 50-90° C.

Curable compositions of the present invention can be used as photosemiconductor sealing material. Thus, in one embodiment of the present invention photosemiconductor sealing material compositions of a curable silicone composition of the present invention are offered.

Hardened material of the present invention will next be described in detail. Hardened material of a curable silicone composition of the present invention is characterized in that it is constituted by curing a curable silicone composition described above. There is no particular restriction as to the form of the hardened material; for example, it can be in the form of a sheet or film, etc. Hardened material can be handled as a single item as such, but it can be handled in a state covering or sealing a photosemiconductor element, etc.

A photosemiconductor device of the present invention will next be described in detail. A photosemiconductor device of the present invention is characterized in that the photosemiconductor element(s) is/are sealed with hardened material of a curable silicone composition described above. Examples of such photosemiconductor devices of the present invention include light-emitting diodes (LEDs), photocouplers and charge-coupled elements (CCDs). Examples of photosemiconductor devices also include light-emitting diode (LED) chips and solid-state imaging elements.

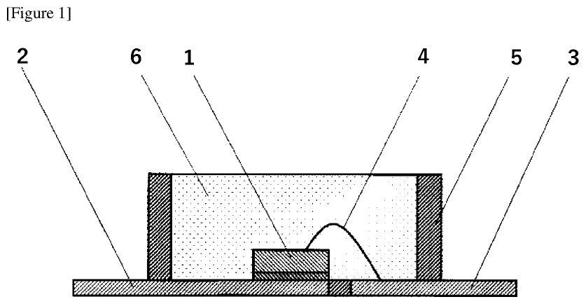

A cross-sectional drawing of a surface-mounted LED which is an example of a photosemiconductor device of the present invention is presented in FIG. 1. In the LED shown in FIG. 1, the light-emitting element (LED chip) 1 is die-bonded onto a lead frame 2, and this light-emitting element (LED chip) 1 and lead-frame 3 are wide-bonded with bonding wire 4. A frame member 5 is set around this light-emitting element (LED chip) 1, and the light-emitting element (LED chip) 1 is sealed inside this frame 5 with hardened material of a curable silicone composition 6.

In one example of a process for producing the surface-mounted LED shown in FIG. 1, the light-emitting element (LED chip) 1 is die-bonded onto a lead frame 2, and this light-emitting element (LED chip) 1 and lead-frame 3 are wire-bonded with metal bonding wire 4; then a curable silicone composition of the present invention is filled inside the frame member 5 set around this light-emitting element (LED chip) 1, followed by curing by heating at 50-200° C. and preferably 50-90° C.

### Examples

The present invention is described in more detail below by means of examples; however, the present invention is not restricted to the description in the examples.
Example, reference example and comparative example curable silicone compositions with the compositions shown in Table 1 were prepared by using the constituents below. In the formulae below Me represents a methyl group, Vi represents a vinyl group, Ph represents a phenyl group, and Ep represents a 3-glycidoxypropyl group.

The following constituents were employed as constituent (A).

Constituent (A-1)

Dimethylpolysiloxane with both ends of the molecular chain terminated with dimethylvinylsiloxy groups, having the formula:

(Me2ViSiO1/2)2(Me2SiO2/2)150

(vinyl group content=0.4 wt %; viscosity=380 mPa·s);

Constituent (A-2)

Dimethylpolysiloxane with both ends of the molecular chain terminated with dimethylvinylsiloxy groups, having the formula:

(Me2ViSiO1/2)2(Me2SiO2/2)310

(vinyl group content=0.2 wt %; viscosity=2000 mPa·s);

Constituent (A-3)

Dimethylpolysiloxane with both ends of the molecular chain terminated with dimethylvinylsiloxy groups, having the formula:

(Me2ViSiO1/2)2(Me2SiO2/2)40

(vinyl group content=1.5 wt %; viscosity=60 mPa·s);

The following constituent was employed as constituent (B).

Constituent (B-1)

Vinyl-group-containing organopolysiloxane resin, having the average compositional formula: (Me2ViSiO1/2)2 (Me2SiO2/2)310

(vinyl group content=2.4 wt %; solid at 25° C.);

Constituent (B-2)

Vinyl-group-containing organopolysiloxane resin, having the average compositional formula: (Me2ViSiO1/2)0.11 (Me3SiO1/2)0.34 (SiO4/2)0.55

(vinyl group content=4.2 wt %; solid at 25° C.);

The following constituents were employed as constituent (C).

Constituent (C-1)

Organohydrogenpolysiloxane resin, having the average compositional formula: (Me2HSiO1/2)0.62 (SiO4/2)0.38

(silicon-atom-bonded hydrogen atom content=0.9 wt %; viscosity=30 mPa·s; number average molecular weight (Mn)=1300; weight average molecular weight (Mw)=1700, molecular weight distribution (Mw/Mn)=1.3, with a network molecular structure)

Constituent (C-2)

Organohydrogenpolysiloxane resin, having the average compositional formula: (Me2HSiO1/2)0.60 (PhSiO3/2)0.40

(silicon-atom-bonded hydrogen atom content=0.65 wt %, number average molecular weight (Mn)=700, weight average molecular weight (Mw)=750, molecular weight distribution (Mw/Mn)=1.1, with a network molecular structure);

The following constituent was employed as constituent (C).

Constituent (D-1)

Dimethylpolysiloxane with both ends of the molecular chain terminated with dimethylhydrogensiloxy groups, having the formula: (Me2HSiO1/2)2 (Me2SiO2/2)20

(silicon-atom-bonded hydrogen atom content=0.1 wt %, viscosity=20 mPa·s).

The following constituent was employed as constituent (E).

Constituent (E-1): 1,3-divinyl-1,1,3,3-tetramethyldisiloxane solution of platinum-1,3-divinyl-1,1,3,3-tetramethyldisiloxane complex (platinum content=3 mass %)

It should be noted that in Table 1, the content of constituent (E) is shown as mass of platinum metal relative to the total mass of organopolysiloxane having an alkenyl groups bound to a silicon atom and organopolysiloxane having hydrogen atoms bound to a silicon atom (ppm: parts per million).

The following constituent was employed as constituent (F).

Constituent (F-1): Ethynylcyclohexan-1-ol.

The following constituent was employed as constituent (G).

Constituent (G-1)

organopolysiloxane, having the average compositional formula: (MeViSiO2/2)1 (Me2SiO2/2)1 (EpSiO3/2)1

(vinyl group content=5.5 wt %).

In the tables, H/Vi represents (total mols of hydrogen atoms bound to a silicon atom in the total organopolysiloxane included in the composition)/(total mols of vinyl groups bound to a silicon atom in the total organopolysiloxane included in the composition).

The curable silicone compositions of the different examples, reference examples and comparative examples were prepared by mixing all of the ingredients uniformly with the compositions (parts by mass) shown in Tables 1-3. The properties of the curable silicone compositions thus prepared were specified by the methods indicated below. The results are presented in Tables 1-3. It should be noted that an empty properties column in Tables 1-3 indicates that the respective property was not measured for that composition.

### Curing Time at 90° C.

With 6 g of the curable silicone composition in a moving die rheometer (MDR), the time for torque to reach a plateau at 90° C. was taken to be the curing time when the entire composition had been cured. A curing time within 5 minutes was taken to be conformity. In the tables “min” means “minutes”.

### Viscosity

The viscosities of each of the constituents and of each of the compositions were measured employing a rotational viscometer in accordance with JIS K7117-1: specifically, they were measured at 25° C. using an Anton Paar MCR 302, with a 40 mm2 cone plate, at a constant shear-speed of 20/s.

### Transmittance of the Hardened Material

Hardened material 2-mm thick was produced from 3 g of the curable composition heated for 5 minutes at 90° C. using a metal mold (10 mm×50 mm×2 mm). The transmissivity of the hardened material (wavelength 450 nm) was measured. Transmissivity of ≥90% was taken to be conformity.

### Curing Shrinkage

Hardened material was produced from 30 g of the curable composition by pressing for 5 minutes at 90° C. using a metal mold (10 cm×15 cm×1 mm); this hardened material was cooled to ambient temperature and then the dimensions were measured and the percentage change in dimensions was taken to be curing shrinkage. Within 1% was taken to be conformity. This curing shrinkage is equivalent to volume shrinkage in the composition during curing.

TABLE 1

| | | | Example 1 | Example 2 | Example 3 | Example 4 | Example 5 | Example 6 | Example 7 |
|---|---|---|---|---|---|---|---|---|---|
| Composition | (A) Constituent | (A-1) | 52.5 | 58.1 | 37.8 | 26.4 | | 41.2 | 47.6 |
| constituent | | (A-2) | | | | | | | |
| | | (A-3) | | | | | 21.1 | | |
| | (B) Constituent | (B-1) | 30.3 | 30.2 | 40.0 | 49.1 | | 30.2 | 30.2 |
| | | (B-2) | | | | | 49.3 | | |
| | (C) Constituent | (C-1) | 3.5 | 4.5 | 4.5 | | 7.3 | 1.7 | 2.8 |
| | | (C-2) | | | | 7.3 | | | |
| | (D) Constituent | (D-1) | 13.2 | 6.6 | 17.2 | 16.7 | 21.7 | 26.4 | 18.9 |
| | (E) Constituent | (E-1) | 8 ppm | 8 ppm | 8 ppm | 8 ppm | 8 ppm | 8 ppm | 8 ppm |
| | (F) Constituent | (F-1) | 0.02 | 0.02 | 0.02 | 0.02 | 0.02 | 0.02 | 0.02 |
| | (G) Constituent | (G-1) | 0.5 | 0.5 | 0.5 | 0.5 | 0.5 | 0.5 | 0.5 |

| | | | | | | | | |
|---|---|---|---|---|---|---|---|---|
| Property | H/Vi | 1.3 | 1.4 | 1.5 | 1.4 | 1.5 | 1.4 | 1.4 |
| | Curing time at 90° C. | 2 min | 2 min | 1 min | 1 min | 2 min | 1 min | 1 min |
| | Viscosity (mPa · s) | 600 | 600 | 700 | 1000 | 800 | 500 | 600 |
| | Light transmittance | Conformity | Conformity | Conformity | Conformity | Conformity | Conformity | Conformity |
| | Curing shrinkage | 0.50% | 0.50% | 0.50% | 0.50% | 0.50% | 0.50% | 0.50% |

TABLE 2
a.

| | | | Reference | Reference | Reference | Reference |
|---|---|---|---|---|---|---|
| | | | Example 8 | Example 9 | Example 10 | Example 11 |
| Composition | (A) Constituent | (A-1) | | | 51.6 | 49.7 |
| constituent | | (A-2) | 98.3 | 86.4 | 19.5 | |
| | | (A-3) | | | | 46.0 |
| | (B) Constituent | (B-1) | | | | |
| | | (B-2) | | 10.1 | 20.0 | |
| | (C) Constituent | (C-1) | 1.7 | 3.5 | | 3.7 |
| | | (C-2) | | | 8.4 | |
| | (D) Constituent | (D-1) | | | | |
| | (E) Constituent | (E-1) | 1.5 ppm | 1.5 ppm | 8 ppm | 8 ppm |
| | (F) Constituent | (F-1) | 0.02 | 0.02 | 0.02 | 0.02 |
| | (G) Constituent | (G-1) | | | 0.5 | 0.5 |

| | | | | | |
|---|---|---|---|---|---|
| Property | H/Vi | 2 | 1.5 | 1.5 | 1 |
| | Curing time at 90° C. | 1 min | 4 min | 5 min | 5 min |
| | Viscosity (mPa · s) | 700 | 500 | 1000 | 200 |
| | Light transmittance | Conformity | Conformity | Conformity | Conformity |
| | Curing shrinkage | 0.50% | 0.50% | 0.50% | 0.50% |

TABLE 3

| | | | Comparative | Comparative | Comparative | Comparative | Comparative | Comparative | Comparative |
|---|---|---|---|---|---|---|---|---|---|
| | | | Example 12 | Example 13 | Example 14 | Example 15 | Example 16 | Example 17 | Example 18 |
| Composition | (A) Constituent | (A-1) | 39.5 | 64.0 | 39.4 | 50.5 | 51.2 | 31.5 | 38.0 |
| constituent | | (A-2) | 24.7 | | | | | | |
| | | (A-3) | | | | 46.0 | 46.0 | | |
| | (B) Constituent | (B-1) | | 30.3 | 30.3 | | | 30.2 | 30.2 |
| | | (B-2) | 25.3 | | | | | | |
| | (C) Constituent | (C-1) | | 5.5 | | 2.9 | 2.2 | | 1.1 |
| | | (C-2) | 10.0 | | | | | | |
| | (D) Constituent | (D-1) | | | 30.1 | | | 37.7 | 30.2 |
| | (E) Constituent | (E-1) | 8 ppm | 8 ppm | 8 ppm | 8 ppm | 8 ppm | 8 ppm | 8 ppm |
| | (F) Constituent | (F-1) | 0.02 | 0.02 | 0.02 | 0.02 | 0.02 | 0.02 | 0.02 |
| | (G) Constituent | (G-1) | 0.5 | 0.5 | 0.5 | 0.5 | 0.5 | 0.5 | 0.5 |

| | | | | | | | | |
|---|---|---|---|---|---|---|---|---|
| Property | H/Vi | 1.5 | 1.3 | 1 | 0.8 | 0.6 | 1.4 | 1.4 |
| | Curing time at 90° C. | >5 min | >10 min | >10 min | 8 min | >10 min | >10 min | >10 min |
| | Viscosity (mPa · s) | | | | | | 200 | 400 |
| | Light transmittance | | | | | | Conformity | Conformity |
| | Curing shrinkage | | | | | | 0.50% | 0.50% |

As shown in the reference examples and the comparative examples, rapid curing within 5 minutes was possible with a content of constituent (B) (i.e. organopolysiloxane resin having at least two alkenyl groups bound to a silicon atom per molecule) in the curable silicone composition of up to 0-20 mass % based on the total mass of organopolysiloxane having at alkenyl groups bound to silicon atoms and organopolysiloxane having hydrogen atoms bound to silicon atoms, but curing within 5 minutes could not be achieved when the quantity of constituent (B) was 25 mass % to 30 mass %. As shown in the examples, even when the content of constituent (B), based on the total mass of organopolysiloxane having at alkenyl groups bound to silicon atoms and organopolysiloxane having hydrogen atoms bound to silicon atoms in the composition, is ≥30 mass % curing within 5 minutes could be achieved by including suitable quantities of both constituent (C) (organohydrogenpolysiloxane resin which has a network molecular structure with at least two hydrogen atoms bound to a silicon atom per molecule) and constituent (D) (straight-chain organohydrogenpolysiloxane having at least two hydrogen atoms bound to a silicon atom per molecule, with hydrogen atoms bound to a silicon atom only present at the two ends of the molecule). Moreover, in the examples the viscosity of the composition, the light transmittance of the hardened material, and curing shrinkage during curing of the compositions were also at the desired levels.

As regards the relationship between the value of (total mols of hydrogen atoms bound to a silicon atom in the total organopolysiloxane included in the composition)/(total mols of alkenyl groups bound to a silicon atom in the total organopolysiloxane included in the composition) in the curable silicone composition and curing speed, Reference to the results of the examples, reference examples and comparative examples indicates that curing within 5 minutes can be achieved in the present invention when this ratio is ≥1.

### INDUSTRIAL APPLICABILITY

Curable compositions of the present invention can be used as sealing materials or covering materials for photosemiconductors such as light-emitting diodes LEDs).

### KEY

1 Light-emitting element
2 Lead frame
3 Lead frame
4 Bonding wire
5 Frame member
6 Hardened material of a curable silicone composition

1. A curable silicone composition which is a curable silicone composition which includes
(A) straight-chain organopolysiloxane which has at least two alkenyl groups bound to silicon atoms per molecule, and a total quantity of aryl groups bound to silicon atoms of ≥0 mol % and <5 mol % based on the total mols of organic groups bound to silicon atoms: 20-74 mass % based on the total mass of organopolysiloxane having alkenyl groups bound to a silicon atoms and organopolysiloxane having hydrogen atoms bound to a silicon atom in the aforementioned composition,
(B) organopolysiloxane resin having at least two alkenyl groups bound to silicon atoms per molecule: 20 mass % to 50 mass % based on the total mass of organopolysiloxane having alkenyl groups bound to a silicon atoms and organopolysiloxane having hydrogen atoms bound to a silicon atom in the aforementioned composition,
(C) organohydrogenpolysiloxane resin which has a network molecular structure with at least two hydrogen atoms bound to a silicon atom per molecule: 1-15 mass % based on the total mass of organopolysiloxane having at alkenyl groups bound to a silicon atom and organopolysiloxane having hydrogen atoms bound to a silicon atom in the aforementioned composition,
(D) straight-chain organohydrogenpolysiloxane having at least two hydrogen atoms bound to a silicon atom per molecule, with hydrogen atoms bound to a silicon atom only present at the two ends of the molecule: 5-27 mass % based on the total mass of organopolysiloxane having alkenyl groups bound to a silicon atom and organopolysiloxane having hydrogen atoms bound to a silicon atom in the aforementioned composition, where the mass percentage above for constituent (D) in the composition is higher than the mass percentage for constituent (C), and
(E) a hydrosilylation reaction catalyst: a quantity, which is a catalytic quantity, of <15 ppm as the quantity of metal atoms included in the catalyst based on the total mass of organopolysiloxane having an alkenyl groups bound to a silicon atom and organopolysiloxane having hydrogen atoms bound to a silicon atom in the aforementioned composition, and
(total mols of hydrogen atoms bound to silicon atoms in the total organopolysiloxane included in the aforementioned composition)/(total mols of alkenyl groups bound to silicon atoms included in the aforementioned composition)=1-3.

2. A hardened material of a curable silicone composition set forth in claim 1.

3. A photosemiconductor sealing material composition comprising a curable silicone as set forth in claim 1.

4. A photosemiconductor device in which the photosemiconductor element is sealed with hardened material of a curable silicone composition as set forth in claim 1.

5. A process for producing photosemiconductor devices, which includes sealing of photosemiconductor elements with hardened material of a curable silicone composition as set forth in claim 1.
